(19) United States
(12) Patent Application Publication
(10) Pub. No.: US 2016/0122179 A1
(43) Pub. Date: May 5, 2016

(54) SENSOR PACKAGE AND MANUFACTURING METHOD THEREOF

(71) Applicant: SAMSUNG ELECTRO-MECHANICS CO., LTD., Suwon-Si (KR)

(72) Inventor: Jin Su KIM, Suwon-Si (KR)

(21) Appl. No.: 14/673,770

(22) Filed: Mar. 30, 2015

(30) Foreign Application Priority Data
Oct. 31, 2014 (KR) 10-2014-0150613

(51) Int. Cl. B81B 7/00; B81C 1/00

(52) U.S. Cl. CPC B81B 7/007; B81C 1/00269

(57) ABSTRACT

The sensor package according to an exemplary embodiment in the present disclosure includes a substrate; and at least one sensor chip mounted on a surface of the substrate, wherein the sensor chip is mounted on the substrate using a face-down bonding scheme.

### CROSS-REFERENCE TO RELATED APPLICATION

This application claims the priority and benefit of Korean Patent Application No. 10-2014-0150613 filed on Oct. 31, 2014, with the Korean Intellectual Property Office, the disclosure of which is incorporated herein by reference.

### BACKGROUND

The present disclosure relates to a sensor package and a manufacturing method thereof.

In various industry fields such as robots, a variety of precision instruments, and the like, an accelerator sensor has been widely used. Recently, demand for semiconductor accelerator sensors using a micro electro mechanical system (MEMS) technology has been rapidly increased.

The semiconductor accelerator sensor has generally a configuration in which a mass body forming a sensor part is stored in an internal storage space of a package formed of a ceramic material. In addition, in order to protect the mass body, the storage space is sealed using a cap.

In accordance with a semiconductor accelerator sensor according to related art, after a sensor chip is seated on a substrate, an exposed electrode and a pad of the substrate are connected to an upper surface by a bonding wire. Therefore, since the process is complex and a mounting area is also increased due to the boding wire, there is a limit in miniaturizing the package.

### RELATED ART DOCUMENT

(Patent Document 1) Korean Patent Laid-Open Publication No. 1999-0036491

### SUMMARY

An aspect of the present disclosure may provide a sensor package capable of being easily manufactured and miniaturized, and a manufacturing method thereof.

According to an aspect of the present disclosure, a sensor package may include: a substrate; and at least one sensor chip mounted on a surface of the substrate, wherein the sensor chip is mounted on the substrate using a face-down bonding scheme.

According to another aspect of the present disclosure, a method of manufacturing a sensor package may include: preparing a base having at least one electrode block formed thereon and having at least one electrode formed on a surface of the electrode block; and forming a sensor chip by bonding a cap to a surface of the base having the electrode block formed thereon.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a cross-sectional view schematically illustrating a sensor package according to an exemplary embodiment in the present disclosure;

FIG. 2 is a cross-sectional view schematically illustrating a sensor chip illustrated in FIG. 1;

FIG. 3 is an exploded perspective view of the sensor chip illustrated in FIG. 2;

FIGS. 4 through 7 are views illustrating a method of manufacturing a sensor chip according to the present exemplary embodiment;

FIGS. 8 through 11 are views illustrating a packing method according to the present exemplary embodiment;

FIG. 12 is a cross-sectional view of a sensor package according to another exemplary embodiment in the present disclosure; and

FIG. 13 is a cross-sectional view of a sensor package according to another exemplary embodiment in the present disclosure.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements maybe exaggerated for clarity, and the same reference numerals will be used throughout to designate the same or like elements.

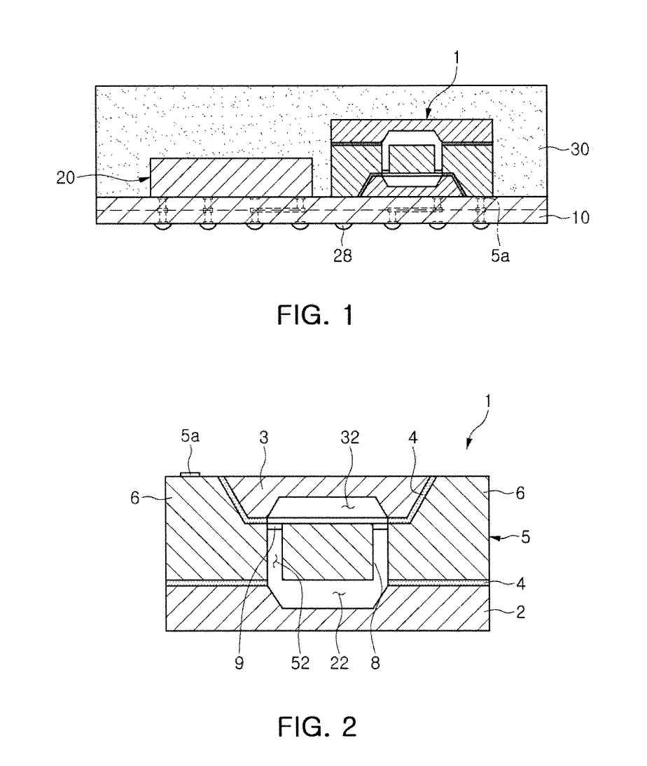

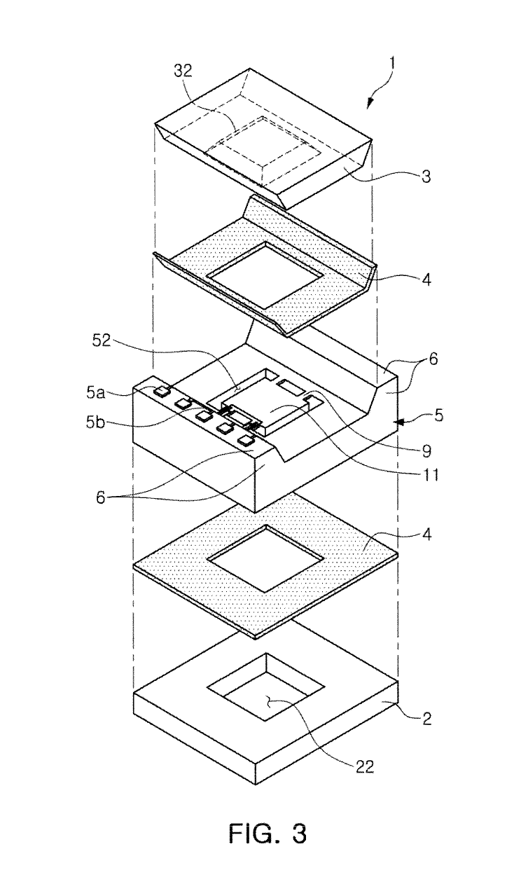

FIG. 1 is a cross-sectional view schematically illustrating a sensor package according to an exemplary embodiment in the present disclosure, FIG. 2 is a cross-sectional view schematically illustrating a sensor chip illustrated in FIG. 1, and FIG. 3 is an exploded perspective view of the sensor chip illustrated in FIG. 2.

Referring to FIGS. 1 through 3, a sensor package 100 according to the present exemplary embodiment may include a sensor chip 1, a substrate 10, and an electronic device 20.

The sensor chip 1 may be the sensor chip 1 that may be manufactured by a micro electro mechanical system (MEMS) process. Therefore, the sensor package 100 maybe formed based on a semiconductor substrate such as a wafer.

The sensor package 100 according to the present exemplary embodiment may include a single sensor chip 1. Here, the sensor chip 1 may be an accelerator sensor, a gyro sensor, a temperature-humidity sensor. However, the sensor chip 1 is not limited thereto, but may include various sensors.

In addition, although the present exemplary embodiment describes a case in which the sensor package 100 includes only the single sensor chip 1 by way of example, the sensor package 100 may also include two or more sensor chips.

The sensor chip 1 according to the present exemplary embodiment may basically include a base 5 and caps 2 and 3. In addition, in the case in which the sensor chip is the accelerator sensor, the sensor chip 1 may include a mass body 8 installed in an internal space 52 of the base 5, as illustrated in FIG. 2.

The mass body 8 and the base 5 may be connected to each other by at least one connection part 9.

One end of the connection part 9 may be connected to the mass body 8 and the other end thereof may be connected to the base 5, and the connection part 9 may serve as a spring for the mass body 8 which is vibrated in proportion to acceleration according to external force.

In addition, the caps 2 and 3 of a cover shape may be each coupled to an upper portion and a lower portion of the base 5 in order to seal the internal space 52 of the base 5.

A lower cap 2 may be coupled to a lower surface of the base 5 and an upper cap 3 may be coupled to an upper surface of the base 5. Here, in the case in which the internal space 52 of the base 5 is formed in a groove shape, not in a through hole shape, the lower cap 2 may be omitted.

A groove 22 capable of expanding the internal space 52 of the base 5 may be formed in an inner side of the lower cap 2. The above-mentioned groove 22 may be formed by an etching process.

The base 5 may have an electrode block 6 formed on the upper surface thereof.

The electrode block 6 may be formed so as to protrude from the upper surface of the base 5 to the outside, wherein one or more electrode blocks 6 may be formed on side portions of the base 5 in which the mass body 8 and the connection part 9 are not formed.

The electrode block 6 may have an upper surface (or distal end) which is formed as a flat surface, on which at least one electrode 5a is formed. The electrode 5a may be electrically connected to a wiring pattern 5b and may be electrically connected to a piezoelectric body formed in the connection part 9, or the like through the wiring pattern 5b.

Therefore, the wiring pattern 5b may be formed along a surface of the electrode block 6 and the upper surface of the base 5. Meanwhile, a position at which the wiring pattern 5b is formed is not limited to the upper surface of the base 5. For example, the wiring pattern 5b may also be formed at other positions, as needed.

In addition, in order to easily form the wiring pattern 5b on the surface of the electrode block 6, an inner side of the electrode block 6 on which the wiring pattern 5b is formed maybe formed as an inclined surface. Therefore, the electrode block 6 maybe formed in a shape in which a cross sectional area is decreased toward the distal end thereof.

According to the present exemplary embodiment, the electrode block 6 may be elongated along both side portions of the base 5 facing each other on the upper surface of the base 5. Therefore, when the upper cap 3 to be described below is bonded to the upper surface of the base 5, since a motion of the upper cap 3 is fixed by the electrode block 6, a bonding process may be easily performed.

However, the shape of the electrode block 6 is not limited thereto, but may be variously deformed.

For example, the electrode block 6 may be discontinuously formed to include a plurality of blocks which are spaced apart from each other by a predetermined distance.

In addition, the electrode block 6 may also be formed so as to protrude along an overall edge of the upper surface of the base 5.

The upper cap 3 maybe formed so as to cover the remaining upper surface of the base 5 except for the portion on which the electrode 5a is formed. As a result, the electrode 5a may be exposed to the outside. Therefore, the upper cap 3 maybe formed in a shape in which it covers portions on which the electrode block 6 is not formed.

In addition, the upper cap 3 maybe formed so as to have the same height (or thickness) as a protruded height of the electrode block 6. Therefore, in the case in which the upper cap 3 is coupled to the base 5, the upper surface of the upper cap 3 and the upper cross section of the electrode block 6 may form one flat surface.

The groove 32 capable of expanding the internal space 52 of the base 5 may also be formed in the upper cap 3 by an etching, or the like.

The base 5, the upper cap 3, and the lower cap 2 according to the present exemplary embodiment may be all formed of the same material. For example, the base 5, the upper cap 3, and the lower cap 2 maybe formed of a silicon material. However, the configuration of present disclosure is not limited thereto. In addition, the upper cap 3 and the lower cap 2 may be bonded to the base 5 by a bonding member 4.

The sensor chip 1 configured as described above may be disposed so that an active surface having the electrode 5a formed thereon faces the substrate 10, and as a result, maybe bonded onto one surface of the substrate 10 by a face-down bonding scheme.

The substrate 10 and the electrode 5a of the sensor chip 1 may be directly bonded to each other. However, the substrate 10 and the electrode 5a of the sensor chip 1 may be electrically connected to each other through a conductive member such as a solder, as needed.

In addition, although not illustrated, the upper cap 2 of the sensor chip 1 and the substrate 10 may have a bonding member such as an adhesive tape or an underfill resin interposed therebetween, thereby increasing adhesion therebetween.

As the substrate 10, various kinds of substrates (e.g., a ceramic substrate, a printed circuit board, a flexible substrate, and the like) well known in the art may be used. In addition, the substrate 10 may include mounting electrodes or wiring patterns (not shown) formed on both surfaces thereof, wherein the mounting electrodes is electrically connected to the sensor chip 1 or the electronic device 20 and the wiring patterns electrically connect the mounting electrodes to each other.

In addition, as the substrate 10 according to the present exemplary embodiment, a semiconductor substrate may be used. Here, the semiconductor substrate may mean a substrate formed through a semiconductor manufacturing process.

The substrate 10 may be a single-layer substrate, or a multi-layer substrate including a plurality of layers, and in this case, circuit patterns for forming electrical connection may be formed between the respective layers.

In addition, the substrate 10 according to the present exemplary embodiment may include conductive vias that electrically connect the mounting electrodes formed on both surfaces of the substrate 10 and the circuit patterns formed in the substrate 10 to each other.

In addition, the substrate 10 according to the present exemplary embodiment may have an external connecting pad formed on the lower surface thereof. The external connecting pad may be electrically connected to an external terminal 28 to be described below.

The electronic device 20 may be an application-specific integrated circuit (ASIC). However, the configuration of present disclosure is not limited thereto.

The electronic device 20 may be bonded to one surface of the substrate 10. The electronic device 20 may have a plurality of electrodes formed therein and may be mounted on the substrate 10 by a flip chip bonding scheme.

Meanwhile, although FIG. 1 illustrates a case in which only a single electronic device 20 is mounted on the substrate 10, the present disclosure is not limited thereto, and other general active devices, passive devices, or semiconductor devices may be further added, as needed.

The sensor package 100 according to the present exemplary embodiment may further include a mold part 30.

The mold part 30 may seal the sensor chip 1 and the electronic device 20 that are mounted on one surface of the substrate 10. In addition, the mold part 1 may enclose outer portions of the devices 1 and 20 and fix the devices 1 and 20 on the substrate 10, thereby securely protecting the devices 1 and 20 from external impact.

The mold part 30 according to the present exemplary embodiment may be formed of an insulating material containing a resin material such as epoxy molding compound (EMC). However, the material of the mold part 30 is not limited thereto.

The mold part 30 according to the present exemplary embodiment may be formed in a form in which it wholly covers one surface of the substrate 10. Meanwhile, the present exemplary embodiment describes a case in which the devices 1 and 20 are embedded in the mold part 30, by way of example. However, the present disclosure is not limited thereto, but various applications may be made. For example, at least one of the devices 1 and 20 embedded in the mold part 30 may have a portion thereof configured to be exposed to the outside of the mold part 30.

The sensor package according to the present exemplary embodiment configured as described above may have the sensor chip mounted on the substrate using a face-down bonding (or flip chip bonding) scheme. Therefore, since a bonding wire may be omitted, amounting area may be reduced and as a result, a size of the package may also be significantly reduced.

In addition, since the sensor chip is generally formed in a hexahedral shape, the overall center of mass may be symmetrical. Therefore, in performing a mechanical operation, stability may be increased.

In addition, since the bonding wire is not used, an increase in a mounting height of the sensor chip according to the loop shape of the bonding wire may be prevented. Therefore, the thickness of the package may also be significantly reduced.

Next, a manufacturing method of a sensor package according to the present exemplary embodiment will be described.

The manufacturing method of the sensor package according to the present exemplary embodiment may be classified into a manufacturing method of a sensor chip and a packaging method of a sensor chip.

First, a manufacturing method of a sensor chip according to the present exemplary embodiment will be described.

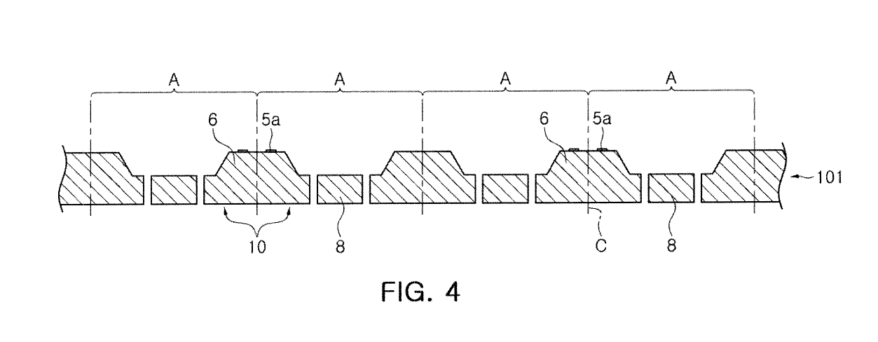

FIGS. 4 through 7 are views illustrating a method of manufacturing a sensor chip according to the present exemplary embodiment.

First, as illustrated in FIG. 4, an operation of preparing a base 5 is performed.

The manufacturing method of the sensor package according to the present exemplary embodiment may use a semiconductor process (e.g., an MEMS process). Therefore, a plurality of sensor packages may be uniformly manufactured in a wafer state, and may be separated into individual sensor chips by cutting the wafer after completing the manufacturing thereof.

Referring to FIG. 4, the base 5 having a mass body 8 disposed in an internal space 52 may be prepared. In this case, the mass body 8 may be connected to the base 5 by a connection part (9 in FIG. 3) and an electrode 5a and the wiring pattern (5b in FIG. 3) may be formed on one surface of the base 5.

In addition, as described above, an electrode block 6 may be formed on one surface of the base 5, that is, an upper surface, and the electrode 5a may be formed on an upper cross section of the electrode block 6. The electrode 5a may be electrically connected to the wiring pattern 5b.

The above-mentioned base 5 may form the internal space 52, the mass body 8, the connection part 9, and the like, by preparing a semiconductor substrate 101 (hereinafter, referred to as a wafer) such as a wafer and partially etching an inner portion of the wafer 101.

Meanwhile, a plurality of bases 5 may be formed on a single wafer 101. Therefore, as illustrated in FIG. 4, the bases 5 maybe classified into the respective separate regions A and may be repeatedly disposed on the single wafer 101.

In this case, the two bases 5 which are disposed to be adjacent to each other may be formed in a form in which they face each other. For example, the two bases 5 which are continuously disposed on the wafer 101 may be formed in a form in which they are vertically symmetrical with each other based on a cutting line C.

Here, the cutting line C may mean a line that cuts the stacked wafers in order to individualize the sensor package 100 in a cutting process to be described below.

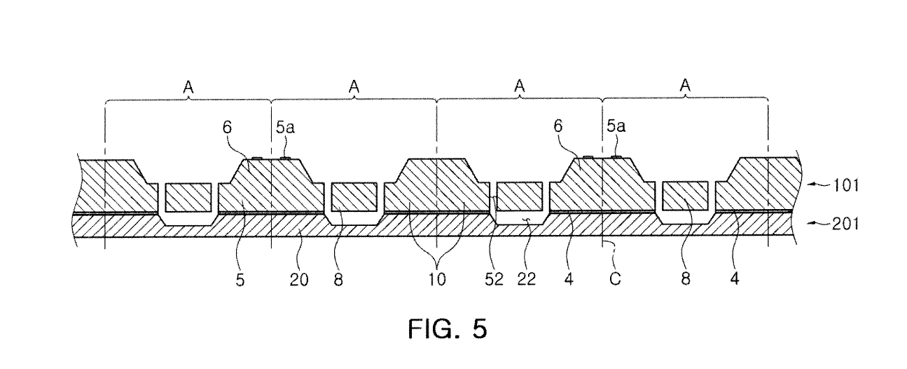

Next, as illustrated in FIG. 5, a lower cap may be bonded to a lower portion of the base 5. The lower cap may be prepared in a state of a wafer 201 similar to the base 5 and may be bonded to a lower portion of the wafer 101 on which the base 5 is formed.

In this case, a groove 22 capable of expanding the internal space 52 of the base 5 may be formed in the wafer 201 of the lower cap 201. The above-mentioned groove 22 may be formed by an etching process.

The wafer 101 of the base and the wafer 201 of the lower cap may be bonded to each other by a bonding member 40 formed of a polymer material or a metal material.

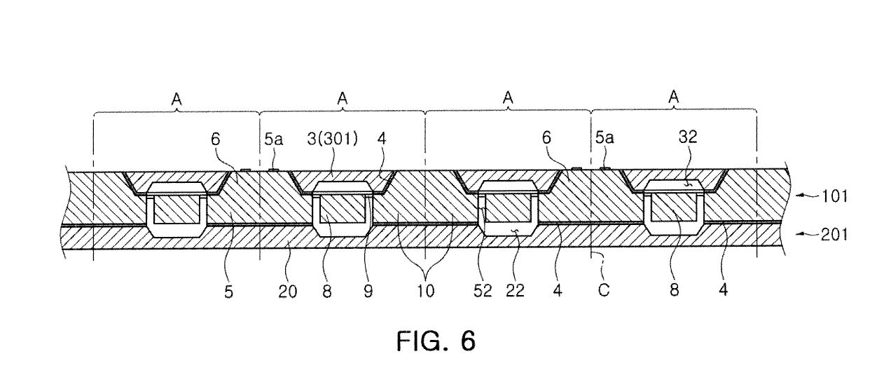

Next, as illustrated in FIG. 6, the upper cap 3 may be attached to the base 5. The upper cap 3 may also be prepared in a state of a wafer 301 similar to the base 5 and may be bonded to an upper portion of the wafer 101 of the base 5.

Meanwhile, although the upper caps 3 are illustrated in FIG. 6 as if they are all separated from each other, the upper caps 3 may be connected to each other by dummy parts in one side which is not illustrated. However, the present disclosure is not limited thereto, but may be variously modified. For example, the respective separated upper caps 3 may be individually bonded, and so forth.

In the case in which a process of stacking the wafers is completed through the above-mentioned processes, a stack wafer in which the wafer 201 of the lower cap and the wafer 301 of the upper cap are each stacked on the lower portion and the upper portion of the wafer 101 of the base may be provided.

Meanwhile, the wafer 101 of the base and the wafer 301 of the upper cap may be bonded to each other by a bonding member 40 formed of a polymer material. However, in the case in which an insulating layer is formed on the wiring pattern 5b, the bonding member formed of a metal material may also be used.

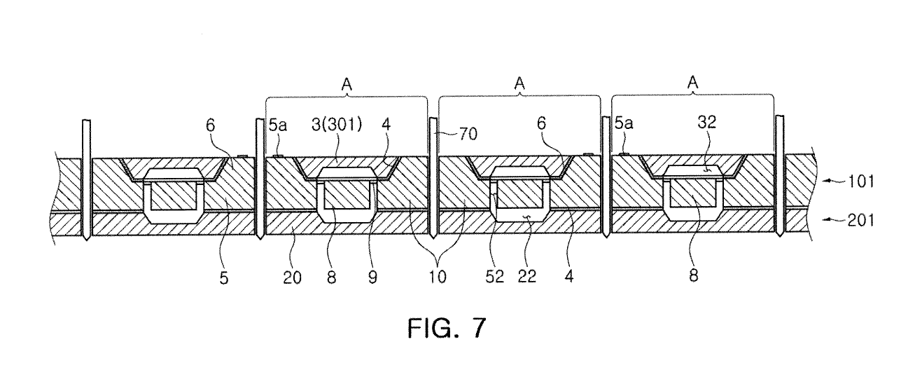

Next, as illustrated in FIG. 7, the stack wafer may be cut along the cutting line C using a blade 70. Thereby, the stack wafer may be divided into individual packages, so as to complete the sensor package 100 according to the present exemplary embodiment illustrated in FIG. 1.

Next, the packaging method of the sensor chip will be described.

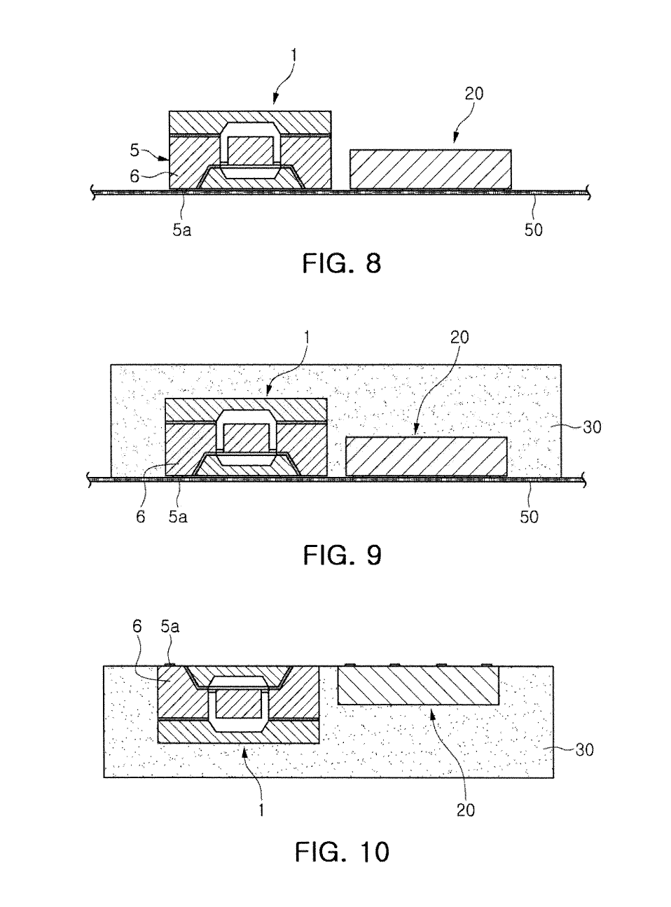

FIGS. 8 through 11 are views illustrating the packing method according to the present exemplary embodiment.

First, as illustrated in FIG. 8, a sensor chip 1 and an electronic device 20 may be disposed on a film 50. Here, as the film 50, an insulating film having flexibility may be used, but the present disclosure is not limited thereto.

In addition, active surfaces of the sensor chip 1 and the electronic device 20 on which the electrodes are formed may be firmly attached to the film. Thereby, an introduction of a molding resin into the active surface of the sensor chip 1 or the electronic device 20 during a process of generating a mold part 30 to be described below may be suppressed.

Next, as illustrated in FIG. 9, an operation of forming a mold part 30 may be performed.

The mold part 30 may be formed by disposing the film 50 on which the devices 1 and 20 are seated in a mold (not illustrate) and then injecting the molding resin into the mold. Therefore, the sensor chip 1 and the electronic device 20 may be protected from the outside by the mold part 30.

Next, as illustrated in FIG. 10, the film 50 may be removed. In the case in which the film 50 is removed, the lower surfaces of the sensor chip 1 and the electronic device 20 may be exposed to the outside, and as a result, the electrode 5a formed on the lower surface may also be exposed to the outside.

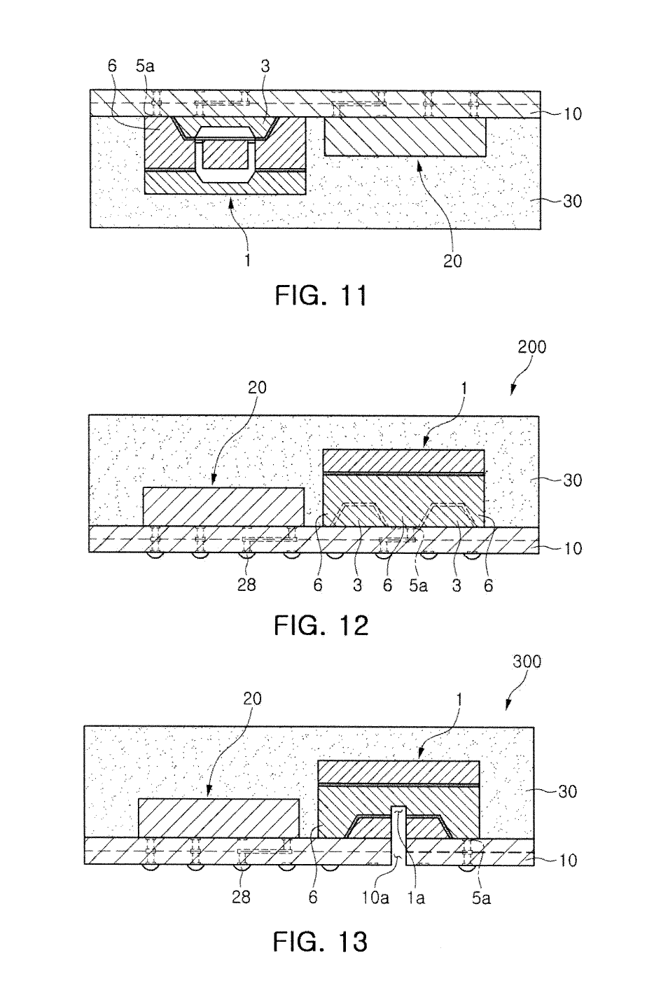

Next, as illustrated in FIG. 11, the substrate 10 may be manufactured. The substrate 10 may be formed by a build-up scheme through a semiconductor process (or a PCB manufacturing process). More specifically, the substrate 10 may be formed by repeatedly performing processes of applying an insulating layer 10a on the lower surfaces of the sensor chip 1 having the electrode 5a exposed therefrom and the electronic device 20 and forming a pattern layer 10b on the insulating layer by an exposure process, or the like.

During the above-mentioned processes, the electrode 5a of the sensor chip 1 and the electrode of the electronic device 20 may be electrically connected to the substrate 10.

In which case in which the formation of the substrate 10 is completed, an external terminal 28 may be formed on the substrate 10. Thereby, the sensor package 100 according to the present exemplary embodiment illustrated in FIG. 1 may be completed. Here, the external terminal 28 may be formed in various forms such as a bump, a solder ball, a pad, and the like, and may be omitted, as needed.

Meanwhile, although the present exemplary embodiment describes a case in which the substrate 10 is manufactured by the semiconductor process by way of example, the present disclosure is not limited thereto.

For example, the sensor package 100 may also be manufactured by manufacturing the substrate 10 separately from the sensor chip 1, mounting the sensor chip 1 on the substrate 10 by the flip chip bonding scheme, and then forming the mold part 30 on one surface of the substrate 10. In this case, the upper cap 3 of the sensor chip 1 and the substrate 10 may have a bonding member such as an adhesive tape or an underfill resin interposed therebetween.

Since the manufacturing method of the sensor package according to the present exemplary embodiment configured as described above may mount the sensor chip on the substrate by the face-down scheme, the substrate may be manufactured by the semiconductor process. Therefore, since a thickness of the substrate may be significantly reduced as compared to a printed circuit board according to the related art which is manufactured by prepreg, a thickness of the package may be significantly reduced.

Meanwhile, the sensor package according to the present disclosure is not limited to the above-mentioned exemplary embodiments, but may be variously modified.

FIG. 12 is a cross-sectional view schematically illustrating a sensor package according to another exemplary embodiment in the present disclosure.

Referring to FIG. 12, a sensor package 200 according to the present exemplary embodiment may have electrode blocks 6 and 6a of the sensor chip 1 that are partially formed on the center of the base 5 as well as both ends of the base 5. In addition, the electrode 5a may also be formed on the electrode block 6a formed at the center of the base.

As such, in the case in which the electrode blocks 6 and 6a are formed at several positions, an area on which the electrode 5a may be formed may also be expanded. Therefore, the electrode 5a and the wiring pattern 5b may be easily disposed.

FIG. 13 is a cross-sectional view schematically illustrating a sensor package according to another exemplary embodiment in the present disclosure.

Referring to FIG. 13, a sensor package 300 according to the present exemplary embodiment may include a temperature-humidity sensor chip 1. In addition, the substrate 10 may be provided with a penetrating part 10a for opening a sensing part la of the sensor chip 1.

Therefore, the sensing part la of the sensor chip 1 may sense temperature or humidity by sensing air introduced into the penetrating part 10a.

As such, since the sensor package 300 according to the present disclosure may be mounted on the substrate 10 by the face-down bonding scheme, various modifications and applications for the sensor chips 1 may be made.

As set forth above, according to exemplary embodiments of the present disclosure, the sensor package may have the sensor chip mounted on the substrate using the flip chip bonding scheme. Therefore, since the bonding wire may be omitted, the mounting area may be reduced and as a result, the size of the package may also be significantly reduced.

In addition, since the sensor chip is generally formed in the hexahedral shape, the overall center of mass may be symmetrical. Therefore, in performing the mechanical operation, stability may be increased.

In addition, since the bonding wire is not used, an increase in a mounting height of the sensor chip according to the loop shape of the bonding wire may be prevented. Therefore, the thickness of the package may also be significantly reduced.

While exemplary embodiments have been shown and described above, it will be apparent to those skilled in the art that modifications and variations could be made without departing from the scope of the present invention as defined by the appended claims.

What is claimed is:

1. A sensor package comprising:
a substrate; and
at least one sensor chip mounted on a surface of the substrate,
wherein the sensor chip is mounted on the substrate using a face-down bonding scheme.

2. The sensor package of claim 1, wherein the sensor chip includes:
a base having at least one electrode block provided thereon and having at least one electrode provided on a surface of the electrode block; and
a cap bonded to a surface of the base on which the electrode block is disposed.

3. The sensor package of claim 2, wherein the electrode block is disposed on both side portions of the surface of the base having a rectangular parallelepiped shape.

4. The sensor package of claim 3, wherein the surface of the electrode block and an outer surface of the cap are disposed on the same plane.

5. The sensor package of claim 3, wherein a cross-sectional area of the electrode block is gradually reduced.

6. The sensor package of claim 5, wherein an inner wall of the electrode block is provided as an inclined surface, and
the inclined surface is provided with a wiring pattern which is electrically connected to the electrode.

7. The sensor package of claim 2, wherein the electrode block is disposed along an edge of the base.

8. The sensor package of claim 1, further comprising at least one electronic device mounted on the substrate.

9. The sensor package of claim 1, further comprising a mold part provided on the surface of the substrate to allow the sensor chip to be embedded therein.

10. The sensor package of claim 1, wherein the sensor chip is an accelerator sensor, a gyro sensor, or a temperature-humidity sensor manufactured using a MEMS process.

11. The sensor package of claim 1, wherein the sensor chip is a temperature-humidity sensor having a sensing part inside an active surface on which an electrode is provided, and
the substrate is provided with a penetrating part exposing the sensing part externally.

12. A sensor package comprising:
at least one sensor chip,
wherein the sensor chip includes:
a base having at least one electrode block provided thereon and having at least one electrode provided on a surface of the electrode block; and
a cap bonded to a surface of the base on which the electrode block is disposed.

13. A method of manufacturing a sensor package, the method comprising:
preparing a base having at least one electrode block formed thereon and having at least one electrode formed on a surface of the electrode block; and
forming a sensor chip by bonding a cap to a surface of the base having the electrode block formed thereon.

14. The method of claim 13, wherein the forming of the sensor chip includes disposing the surface of the electrode block and an outer surface of the cap on the same plane when the cap is bonded to the surface of the base.

15. The method of claim 13, further comprising, after the forming of the sensor chip, mounting the sensor chip on a substrate.

16. The method of claim 13, further comprising, after the forming of the sensor chip, forming a substrate on an active surface of the sensor chip having the electrode formed thereon by using a build-up scheme.

17. The method of claim 16, further comprising, before the forming of the substrate:
attaching the active surface of the sensor chip to a film;
forming a mold part in which the sensor chip is embedded; and
exposing the electrode of the sensor chip by removing the film.

18. The method of claim 17, further comprising, after the forming of the substrate, forming an external terminal on the substrate.
